(19) United States
(12) Patent Application Publication
(10) Pub. No.: US 2025/0081490 A1
(43) Pub. Date: Mar. 6, 2025

(54) SEMICONDUCTOR DEVICE AND METHOD OF MANUFACTURING THE SAME

(71) Applicant: Renesas Electronics Corporation, Tokyo (JP)

(72) Inventor: Kazuhiko IWAKIRI, Tokyo (JP)

(21) Appl. No.: 18/817,322

(22) Filed: Aug. 28, 2024

(30) Foreign Application Priority Data
Aug. 29, 2023 (JP) 2023-139359

(51) Int. Cl. H01L 29/739; H01L 29/06; H01L 29/49; H01L 29/66

(52) U.S. Cl. CPC H10D 12/481; H10D 12/038; H10D 62/127; H10D 64/664

(57) ABSTRACT

The technology of improving the adhesion of the barrier metal film is provided. The semiconductor device includes: a floating region formed between a trench gate electrode and a trench emitter electrode; a stacked film formed on the floating region; an interlayer insulating film formed on the stacked film; a plug penetrating the interlayer insulating film and reaching the stacked film; a barrier metal film formed to cover the interlayer insulating film and the plug; and a metal film formed on the barrier metal film.

### CROSS-REFERENCE TO RELATED APPLICATIONS

The disclosure of Japanese Patent Application No. 2023-139359 filed on Aug. 29, 2023, including the specification, drawings and abstract is incorporated herein by reference in its entirety.

### BACKGROUND

This disclosure relates to a semiconductor device, and can be applied to, for example, an IE type trench gate IGBT.

There is disclosed technique listed below.

[Patent Document 1] Japanese Unexamined Patent Application Publication No. 2023-35453

In an IGBT (Insulated Gate Bipolar Transistor), which is a type of power semiconductor, an emitter wiring may be composed of a barrier metal film and a conductor film, and may be electrically connected to an emitter region and a base region formed on a semiconductor substrate through a via formed in an insulating film (for example, the Patent Document 1).

### SUMMARY

As described above, when the emitter wiring (emitter is formed on the insulating film (interlayer electrode) insulating film) and the via (plug), the adhesion between a barrier metal film and the interlayer insulating film may be low. Other problems and novel features will become apparent from the description and accompanying drawings of this specification.

A brief explanation of a representative one of this disclosure is as follows. That is, the semiconductor device includes a floating region formed between a trench gate electrode and a trench emitter electrode, a stacked film formed on the floating region, an interlayer insulating film formed on the stacked film, a plug that penetrates the interlayer insulating film and reaches the stacked film, a barrier metal film formed to cover the interlayer insulating film and the plug, and a metal film formed on the barrier metal film.

According to the semiconductor device, the adhesion of the barrier metal film is improved.

### BRIEF DESCRIPTION OF THE DRAWINGS

FIG. 1 is a plan view showing the configuration of the semiconductor device in the embodiment.

FIG. 2 is a plan view of a main portion showing a part of the cell formation region of the semiconductor device shown in FIG. 1 in an enlarged manner.

FIG. 3 is a cross-sectional view of the main portion along the line A1-A2 of the semiconductor device shown in FIG. 2.

FIG. 4 is a cross-sectional view showing a manufacturing process of the semiconductor device in the embodiment.

FIG. 5 is a cross-sectional view showing a manufacturing process following FIG. 4.

FIG. 6 is a cross-sectional view showing a manufacturing process following FIG. 5.

FIG. 7 is a cross-sectional view showing a manufacturing process following FIG. 6.

FIG. 8 is a cross-sectional view showing a manufacturing process following FIG. 7.

FIG. 9 is a cross-sectional view showing a manufacturing process following FIG. 8.

FIG. 10 is a cross-sectional view showing a manufacturing process following FIG. 9.

FIG. 11 is a cross-sectional view showing a manufacturing process following FIG. 10.

FIG. 12 is a cross-sectional view showing a manufacturing process following FIG. 11.

FIG. 13 is a cross-sectional view showing a manufacturing process following FIG. 12.

FIG. 14 is a cross-sectional view showing a manufacturing process following FIG. 13.

FIG. 15 is a cross-sectional view showing a manufacturing process following FIG. 14.

FIG. 16 is a plan view of a main portion of the semiconductor device in the comparative example.

FIG. 17 is a cross-sectional view along the line A1-A2 of the semiconductor device shown in FIG. 16.

FIG. 18 is a schematic cross-sectional view showing the configuration of the semiconductor device in the first modified example.

FIG. 19 is a schematic cross-sectional view showing the configuration of the semiconductor device in the second modified example.

### DETAILED DESCRIPTION

Hereinafter, the embodiment will be described using the drawings. However, for the sake of clarity of explanation, the following description and drawings are appropriately omitted and simplified. Also, the width, thickness, shape, etc. of each part may be schematically represented compared to the actual state. Also, the same reference numerals are attached to the same components, and repeated explanations may be omitted.

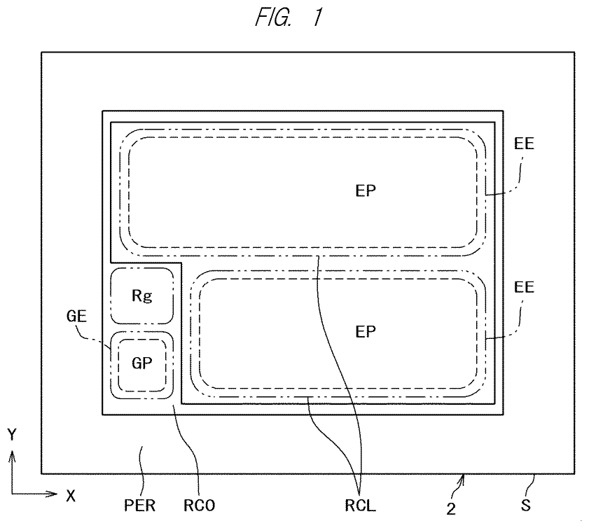

The configuration of the semiconductor device in the embodiment will be described using FIGS. 1, 2, and 3.

As shown in FIG. 1, two directions intersecting, preferably orthogonal, within the surface of the semiconductor substrate (hereinafter, simply referred to as “substrate”) S are defined as the X direction as the first direction and the Y direction as the second direction, and the direction perpendicular to the surface of the substrate S, that is, the up and down direction is defined as the Z direction.

In this specification, a phrase “in plan view” means a case of view from a direction perpendicular to the surface of the substrate S. Also, in this specification, when the conductivity type of the semiconductor is P-type, it means that only holes are charge carriers, or means that both electrons and holes may be charge carriers while the concentration of holes is higher than that of electrons, and holes are the main charge carriers. In this specification, when the conductivity type of the semiconductor is N-type, it means that only electrons may be charge carriers, or means that both electrons and holes may be charge carriers while the concentration of electrons is higher than that of holes, and electrons are the main charge carriers.

As shown in FIG. 1, the semiconductor chip 2 as the semiconductor device has the substrate S. The substrate S has a front surface as one main surface, and a back surface as the other main surface on the opposite side of the front surface. The substrate S also has a cell formation region RCL as a part of the front surface, a cell peripheral connection region RC0, and a chip peripheral part PER. The cell formation region RCL is provided in approximately the central region of the semiconductor chip 2. The cell peripheral connection region RC0 is provided so as to surround the cell formation region RCL. The chip peripheral part PER is provided in the chip peripheral region so as to surround the cell peripheral connection region RC0.

Above the cell formation region RCL, an emitter electrode EE, an emitter pad EP, and unillustrated gate wiring, etc. are provided so as to cover the entire cell formation region RCL. In this example, a gate pad GP, a gate electrode GE, and a built-in gate resistor (resistor element) Rg connected between the gate wiring and the gate electrode GE are provided in the cell peripheral connection region RCO. On the upper surface of the chip peripheral part PER, an unillustrated annular guard ring is provided, and inside it, several (single or multiple) annular field plates connected to an annular floating field ring, etc. are provided.

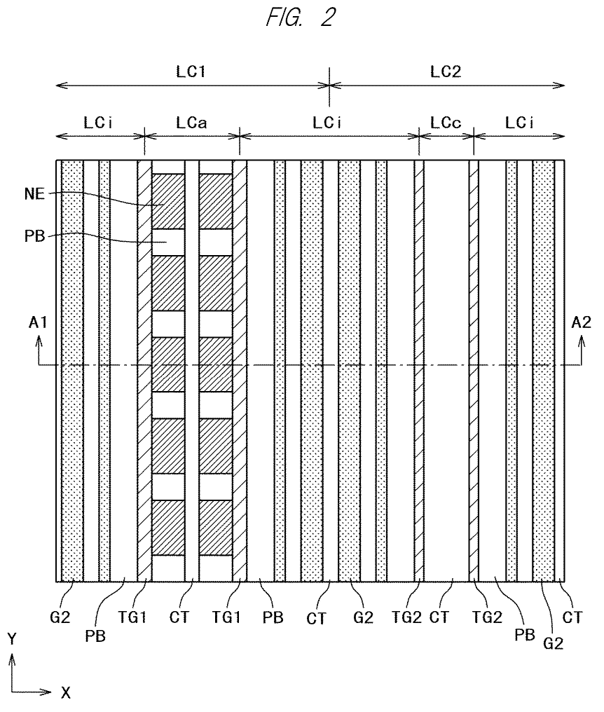

In the cell formation region RCL, cells of an IE (Injection Enhancement) type trench gate IGBT are formed. As shown in FIG. 2, the cell formation region RCL has a trench gate electrode TG1 composed of a trench for gate potential connection between an active cell region LCa and an inactive cell region LCi. Then, the cell formation region RCL has a trench emitter electrode TG2 composed of a trench for emitter potential connection between a hole collector cell region LCc and the inactive cell region LCi such that every other active cell region LCa is replaced with the hole collector cell region LCc. In this specification, this IGBT is called a GGEE type IGBT.

In the cell formation region RCL, unit cell regions are periodically arranged in the X direction. Each unit cell region is composed of a first unit cell region LC1 and a second unit cell region LC2, and in this embodiment, the width (length in the X direction) of the second unit cell region LC2 is narrower than the width of the first unit cell region LC1.

Each first unit cell region LC1 is composed of a central active cell region LCa and a pair of half-width inactive cell regions LCi sandwiching both sides of the active cell region in the X direction.

In each active cell region LCa, two trench gate electrodes TG1 are formed along the Y direction, and separated from each other in the X direction. Therefore, there is the trench gate electrode TG1 between the active cell region LCa and the inactive cell region LCi. The trench gate electrode TG1 is electrically connected to the gate electrode (gate electrode GE shown in FIG. 1). In other words, the trench gate electrode TG1 is a trench gate electrode composed of a trench for gate potential connection. Also, in each active cell region LCa, in a plan view, there are regions where an emitter region NE is formed and regions where the emitter region NE is not formed. A body region PB is provided in the region where the emitter region NE is not formed. The body region PB is also called a channel region, a base region, or a base diffusion layer.

On the other hand, each second unit cell region LC2 is composed of a central hole collector cell region LCc and a pair of half-width inactive cell regions LCi sandwiching both sides of the hole collector cell region in the X direction.

In each hole collector cell region LCc, trench emitter electrodes TG2 are formed along the Y direction, and separated from each other in the X direction. Therefore, there is the trench emitter electrode TG2 between the hole collector cell region LCc and the inactive cell region LCi. The trench emitter electrode TG2 is electrically connected to the emitter electrode EE through a first plug PL1 to be described later. In other words, the trench emitter electrode TG2 is a trench emitter electrode composed of a trench for emitter potential connection. The trench gate electrode TG1 and the trench emitter electrode TG2 are adjacent in the X direction in plan view.

The widths in the X direction of the active cell region LCa and the hole collector cell region LCc are formed narrower than the width in the X direction of the inactive cell region LCi. Also, the active cell region LCa or the hole collector cell region LCc and the inactive cell region LCi are alternately arranged to form the unit cell region.

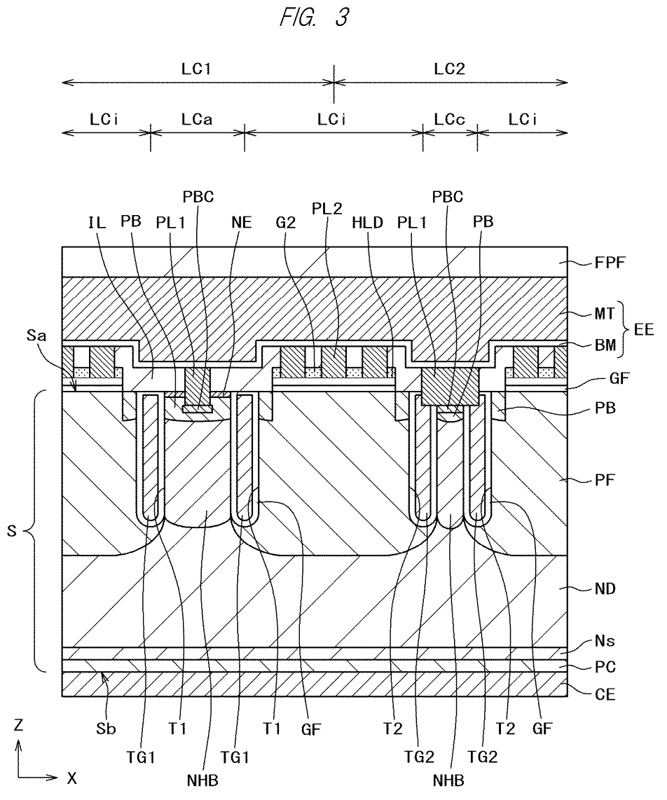

In the active cell region LCa and the hole collector cell region LCc, a contact trench CT extending along the Y direction is provided in the center thereof, and the lower end of the contact trench CT reaches the body contact region PBC (see FIG. 3) formed on the substrate S. A first plug PL1 (see FIG. 3) to be described later is formed in the contact trench CT. In other words, the first plug PL1 extends in the Y direction in plan view.

The distance between the trench emitter electrodes TG2 formed in the hole collector cell region LCc and adjacent to each other in the X direction is smaller than the distance between the trench gate electrodes TG1 formed in the active cell region LCa and adjacent to each other in the X direction. The hole collector cell region LCc has a function of discharging holes injected into the floating region PF.

On the other hand, the width in the X direction of the contact trench CT of the hole collector cell region LCc is larger than the width in the X direction of the contact trench CT of the active cell region LCa. The contact trench CT of the hole collector cell region LCc is formed in contact with the trench emitter electrode TG2. In FIGS. 2 and 3, the contact trench CT is in contact with both of a pair of trench emitter electrodes TG2, but it may be in contact with either of the trench emitter electrodes TG2. In other words, the contact trench CT is formed so as to span between the trench emitter electrode TG2 and the emitter region NE.

In this embodiment, the width of the hole collector cell region LCc is formed narrower than the width of the active cell region LCa, but this is not essential, and the widths of the hole collector cell region LCc and the active cell region LCa may be the same or substantially the same. Making them the same or substantially the same causes an advantage that the hole distribution becomes uniform.

The inactive cell region LCi is provided with a floating region PF. Furthermore, the center of the inactive cell region LCi is provided with contact trenches CT extending along the Y direction and separated from each other, and the lower end of the contact trench CT reaches a conductive film G2 formed on the substrate S. A second plug PL2 (see FIG. 3) to be described later is formed in the contact trench CT. In this embodiment, an example with three contact trenches CT is shown, but at least one contact trench CT is sufficient.

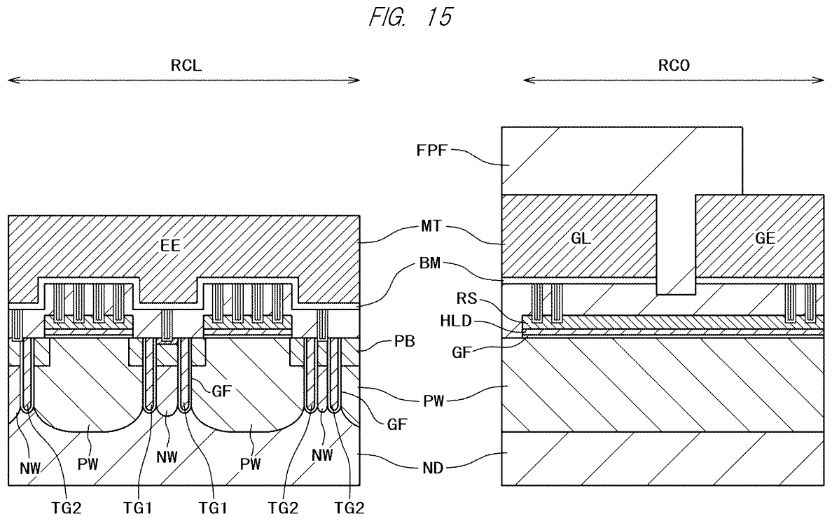

In FIG. 3, the depth of the floating region PF is deeper than the lower ends of the first trench T1 and the second trench T2, and covers the lower ends. As a result, even if the width of the inactive cell region LCi is larger than the width of the active cell region LCa, there is an advantage that it is easy to maintain the withstand voltage. Such a structure is not essential. In other words, the floating region PF may be a structure that does not cover the lower ends of the first trench T1 and the second trench T2. For example, it may be the structure shown in FIGS. 15, 18, and 20. In this embodiment, the width of the active cell region LCa is made narrower than the width of the inactive cell region LCi to enhance the IE effect.

Next, the cross-sectional structure along the line A1-A2 in FIG. 2 will be described using FIG. 3. Note that FIGS. 1 and 2 should be referred to as appropriate.

As shown in FIG. 3, the main part of the substrate S is occupied by the drift layer ND. On the back surface (second main surface, lower surface) Sb side of the substrate S, the field stop region Ns and the collector region PC are provided from the side close to the drift layer ND. Furthermore, a collector electrode CE electrically connected to the collector region PC is provided on the back surface Sb of the substrate S.

On the other hand, on the front surface (first main surface, upper surface) Sa side of the substrate S, the floating region PF or the body region PB is provided on almost the entire surface of the cell formation region RCL.

In the active cell region LCa, the first trench T1 is provided on the front surface Sa side of the substrate S, and its inside includes the trench gate electrode TG1 through the gate insulating film GF. The gate insulating film GF is located at the interface between the trench gate electrode TG1 and the substrate S. The trench gate electrode TG1 is electrically connected to the gate electrode (gate electrode GE shown in FIG. 1). The trench gate electrode TG1 is embedded from the lower end of the trench T1 formed in the substrate S to the upper part.

On the other hand, in the hole collector cell region LCc, the second trench T2 is provided on the front surface Sa side of the substrate S, and its inside includes the trench emitter electrode TG2 through the gate insulating film GF. The gate insulating film GF is located at the interface between the trench emitter electrode TG2 and the substrate S. The trench emitter electrode TG2 is electrically connected to the emitter electrode EE through the first plug PL1 and the barrier metal film BM. The trench emitter electrode TG2 is embedded from the lower end of the second trench T2 formed in the substrate S to the upper part.

In the active cell region LCa, the emitter region NE is provided on the front surface Sa side of the substrate S. The lower end of the first plug PL1 formed in the contact trench CT (see FIG. 2) reaches the body region PB. In other words, the first plug PL1 penetrates the interlayer insulating film IL and reaches the body region PB. The body contact region PBC is provided on the substrate S in contact with the lower end of the first plug PL1 formed in the contact trench CT (see FIG. 2). The hole barrier region NHB is provided under the body region PB. Note that a latch-up prevention region may be provided under the body contact region PBC.

In the hole collector cell region LCc, except that the emitter region NE is not provided, the impurity doping structure is almost the same as that in the active cell region LCa. However, the lower end of the first plug PL1 formed in the contact trench CT (see FIG. 2) reaches the trench emitter electrode TG2 in addition to the body region PB. In other words, the first plug PL1 penetrates the interlayer insulating film IL and reaches the body region PB. The body contact region PBC is provided on the substrate S where the lower end of the contact trench CT (see FIG. 2) reaches.

Although the hole barrier region NHB is also provided in the hole collector cell region LCc as in the active cell region LCa, this is not essential. However, by providing the hole barrier region NHB, the balance of the overall flow of holes can be maintained.

In the inactive cell region LCi, the floating region PF, which is deeper than, for example, the first trench T1 and the second trench T2, is provided under the front surface Sa of the substrate S and the body region PB on the front surface Sa side of the substrate S. Above the gate insulating film GF as the first insulating film formed on the floating region PF, a second insulating film HLD and a conductive film G2 are provided. The gate insulating film GF, the second insulating film HLD, and the conductive film G2 form a stacked film. There is no body region PB under the stacked film. In plan view, the stacked film has an end on the floating region PF, and a step is created by this end. This step is, for example, 50 nm or more in size. Three second plugs PL2 are formed to penetrate into the stacked film. In other words, the second plug PL2 penetrates the interlayer insulating film IL and reaches the stacked film. The second plug PL2 is a dummy plug that is not electrically connected to the substrate S where the floating region PF is formed. In this embodiment, an example with three second plugs PL2 is shown, but at least one second plug PL2 is sufficient.

The interlayer insulating film IL is formed on almost the entire front surface Sa of the substrate S. A barrier metal film BM is formed on the interlayer insulating film IL. In other words, the barrier metal film BM is in contact with the interlayer insulating film IL. A metal film (metallic film) MT is formed on the barrier metal film BM. The barrier metal film BM and the metal film MT constitute the emitter electrode EE.

In the active cell region LCa, the emitter electrode EE is connected to the emitter region NE, the body region PB, and the body contact region PBC through the first plug PL1 embedded in the contact trench CT. In the hole collector cell region LCc, the emitter electrode EE is connected to the body region PB and the body contact region PBC through the first plug PL1 embedded in the contact trench CT. In other words, the first plug PL1 is electrically connected to the body region PB. The barrier metal film BM is in contact with the first plug PL1.

In the inactive cell region LCi, the emitter electrode EE is connected to the conductive film G2 through the second plug PL2 embedded in the contact trench CT. In other words, the second plug PL2 is not electrically connected to the floating region PF and the body region PB. The barrier metal film BM is in contact with the second plug PL2.

An insulating film FPF as a passivation film is formed on the emitter electrode EE. Although not shown, a conductive film called OPM (Over Pad Metal) is formed on the emitter electrode EE included in the emitter pad EP and the gate electrode GE included in the gate pad GP.

### Method of Manufacturing Semiconductor Device

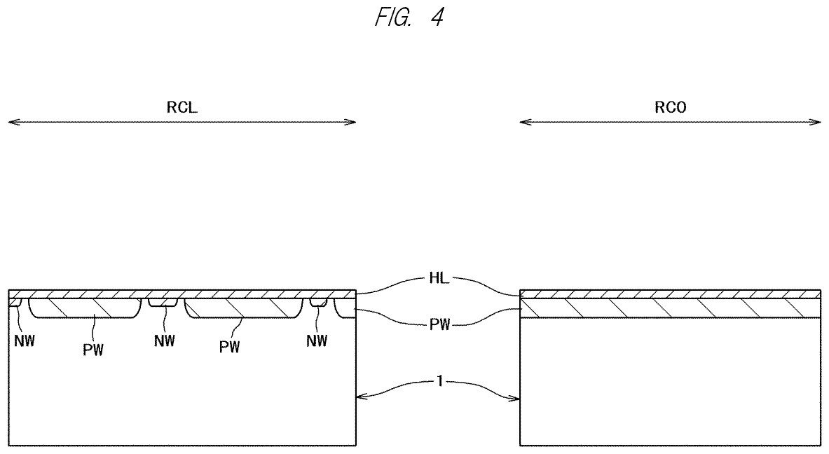

Next, the method of manufacturing the semiconductor device in the embodiment will be explained using FIGS. 4 to 15. FIGS. 4 to 15 show the cell formation region RCL on the left side and the cell peripheral connection region RCO where a resistor Rg is formed, on the right side. Refer to FIG. 3 as appropriate. In FIG. 3, three second plugs PL2 are formed on one floating region PF, but FIGS. 4 to 15 show an example of forming four second plugs PL2.

First, a semiconductor wafer 1 including a silicon single crystal substrate S into which an N-type impurity such as phosphorus as a first conductive type has been introduced is prepared. The semiconductor wafer 1 is hereinafter simply referred to as the wafer 1. The wafer 1 has a front surface as a first main surface and a back surface as a second main surface opposite to the front surface.

The term “wafer” used in this specification may mean the wafer itself or a stacked body of the wafer and a predetermined layer or film formed on the surface of the wafer. The term “surface of the wafer” used in this specification may mean the surface itself of the wafer or the surface of a predetermined layer or the like formed on the wafer.

Next, as shown in FIG. 4, by introducing an N-type impurity into the substrate S on the front surface side of the wafer 1 by ion implantation using a resist pattern as a mask, an N-type well region NW is formed. Note that the N-type well region NW is formed in the active cell region LCa and the hole collector cell region LCc.

Subsequently, by introducing a P-type impurity as a second conductivity type into the substrate S on the front surface side of the wafer 1 by ion implantation using a resist pattern as a mask, a P-type well region PW is formed. Note that the P-type well region PW is formed in the inactive cell region LCi. Also, when the P-type well region PW is formed in the cell formation region RCL, the P-type well region PW is formed in the cell peripheral connection region RCO.

Subsequently, an insulating film HL is formed by, for example, the CVD method of forming silicon oxide (SiO₂) on the front surface of the wafer 1.

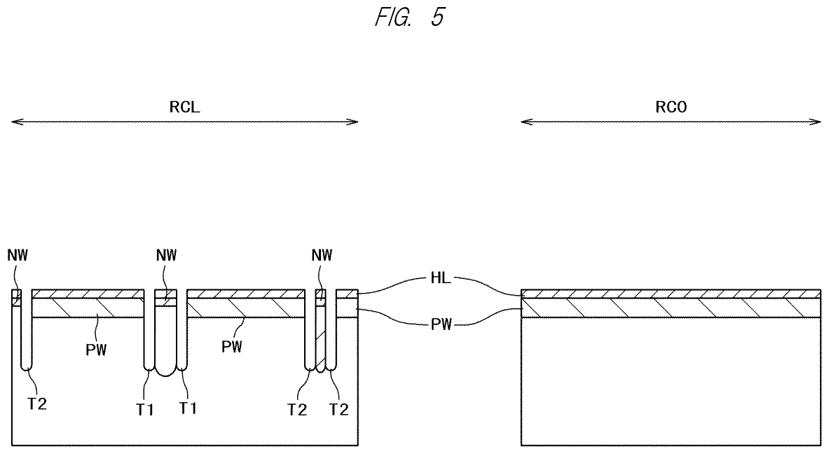

Next, as shown in FIG. 5, patterning of the insulating film HL is performed by, for example, dry etching using a resist pattern as a mask. Subsequently, the first trench T1 and the second trench T2 are formed by, for example, anisotropic dry etching using the insulating film HL as a hard mask. Subsequently, the insulating film HL is removed by, for example, dry etching.

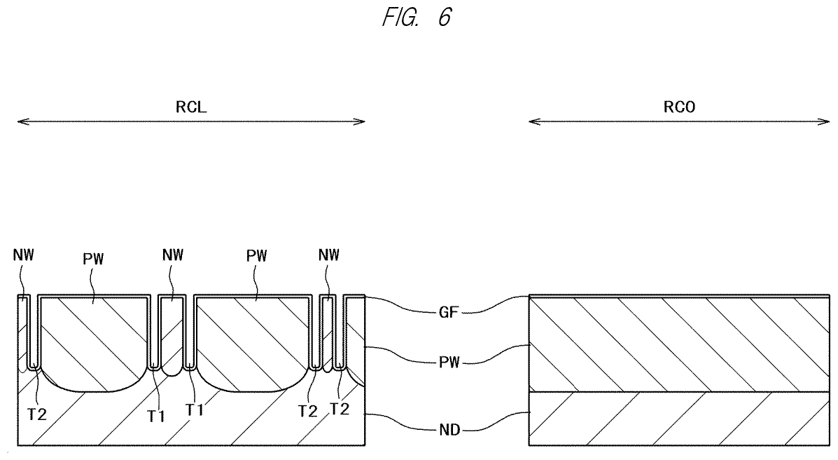

Next, as shown in FIG. 6, a drive-in diffusion is performed for the P-type well region PW and the N-type well region NW. At this time, the drive-in diffusion is performed so that the end of the P-type well region PW on the back surface side of the wafer 1 is arranged at the ends of the first trench T1 and the second trench T2 on the back surface side of the wafer 1 in the Z-axis direction. Subsequently, a gate insulating film GF is formed by, for example, thermal oxidation or the like of forming, for example, SiO₂ on the front surface of the wafer 1 and on the inner walls of the first trench T1 and the second trench T2. As a result, the gate insulating film GF (first insulating film) on the floating region PF is formed in the same layer as the gate insulating film GF of the trench gate electrode TG1 and the trench emitter electrode TG2.

By the above drive-in diffusion, a P-type well region PW is formed between the first trench T1 and the adjacent second trench T2. Preferably, the P-type well region PW makes contact with the gate insulating film GF formed on the inner wall of the first trench T1 and the gate insulating film GF formed on the inner wall of the second trench T2.

Also, the N-type well region NW is formed between the first trench T1 and the first trench T1 and between the second trench T2 and the second trench T2. Preferably, the N-type well region NW formed between the first trench T1 and the first trench T1 makes contact with the gate insulating film GF formed on the inner wall of the first trench T1. Also, preferably, the N-type well region NW formed between the second trench T2 and the second trench T2 makes contact with the gate insulating film GF formed on the inner wall of the second trench T2.

Furthermore, during the aforementioned drive-in diffusion, the region of the N-type wafer 1 where the P-type well region PW and N-type well region NW are not formed becomes the drift layer ND shown in FIG. 3. The P-type well region PW in the cell formation region RCL becomes the floating region PF shown in FIG. 3. The N-type well region NW becomes the hole barrier region NHB shown in FIG. 3. The drift layer ND is also referred to as the N-type drift layer. The floating region PF is also referred to as the P-type floating region. The hole barrier region NHB is also referred to as the N-type hole barrier region. FIG. 6 shows that the floating region PF does not cover the lower ends of the first trench T1 and the second trench T2.

Between the first trench T1 and the first trench T1, the N-type impurity concentration of the hole barrier region NHB is higher than the N-type impurity concentration of the drift layer ND, and is lower than the N-type impurity concentration of the emitter region NE, which will be described later.

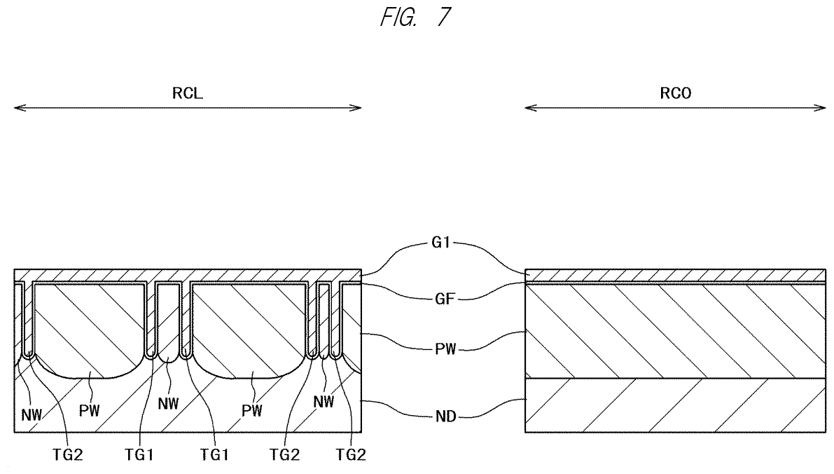

Next, as shown in FIG. 7, the conductive film G1 is formed by, for example, the CVD (Chemical Vapor Deposition) method or the like of depositing poly-silicon which has been doped with phosphorus, on the front surface of the wafer 1 and inside the first trench T1 and the second trench T2.

Subsequently, the conductive film G1 is etched back by, for example, the dry etching method. This forms the trench gate electrode TG1, which includes the conductive film G1 embedded inside the first trench T1 through the gate insulating film GF. Also, this forms the trench emitter electrode TG2, which includes the conductive film G1 embedded inside the second trench T2 through the gate insulating film GF.

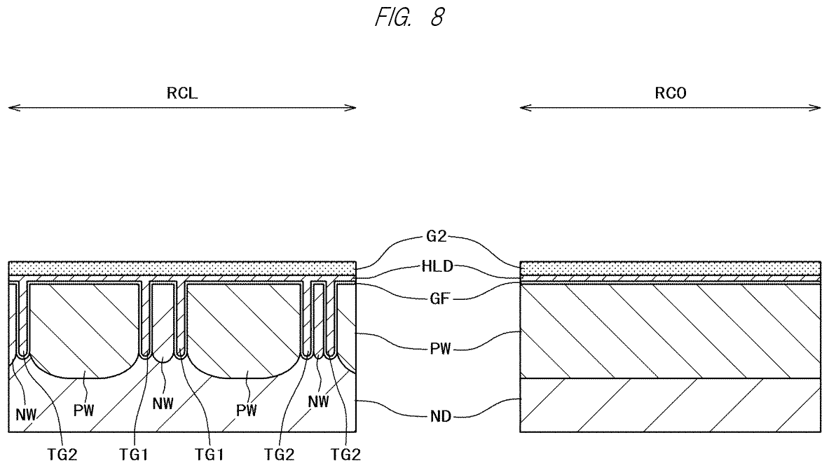

Next, as shown in FIG. 8, a second insulating film HLD is formed by, for example, the CVD method of depositing SiO₂ on the front surface of the wafer 1. Subsequently, a conductive film G2 is formed by, for example, the CVD method of depositing poly-silicon which has not been doped with an impurity, on the front surface of the wafer 1.

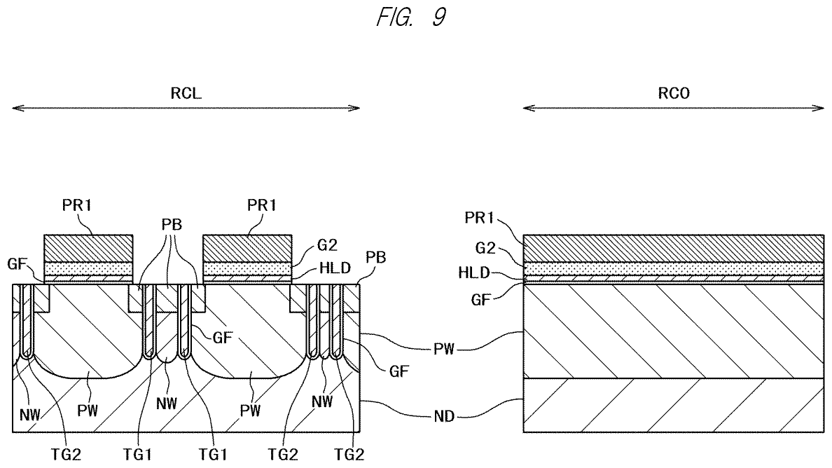

Next, as shown in FIG. 9, a stacked film is formed by, for example, the dry etching method of patterning the gate insulating film GF, the second insulating film HLD, and the conductive film G2, using a resist pattern PRI as a mask. Here, the thickness of the conductive film G2 is larger than the thickness of the second insulating film HLD, and the thickness of the second insulating film HLD is larger than the thickness of the gate insulating film GF. Subsequently, the body region PB is formed by the ion implantation method of introducing the P-type impurity into the entire surface of the cell formation region RCL and other necessary parts, using the resist pattern PRI as a mask. The body region PB is also referred to as the P-type body region.

Specifically, the body region PB is formed between the first trench T1 and the first trench T1 and between the second trench T2 and the second trench T2 so as to make contact with the gate insulating film GF formed on the inner wall of the first trench T1 and the gate insulating film GF formed on the inner wall of the second trench T2. This body region PB is formed on the hole barrier region NHB. Also, in the inactive cell region LCi, this body region PB is formed where there is no second insulating film HLD and conductive film G2 on the floating region PF.

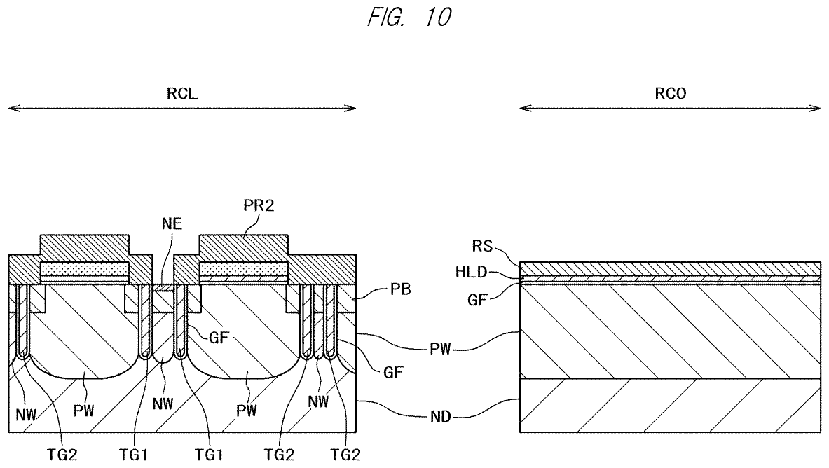

Furthermore, as shown in FIG. 10, the emitter region NE is formed by the ion implantation method of introducing an N-type impurity into the upper layer of the body region PB in the active session of the active cell region LCa, using a resist pattern PR2 as a mask. The emitter region NE is also referred to as the N+ type emitter region. Also, in the cell peripheral connection region RC0, a resistance film RS is formed by introducing an N-type impurity into the conductive film G2. Note that the trench gate electrode TG1 penetrates the emitter region NE and the body region PB and reaches the drift layer ND. The trench emitter electrode TG2 penetrates the body region PB and reaches the drift layer ND.

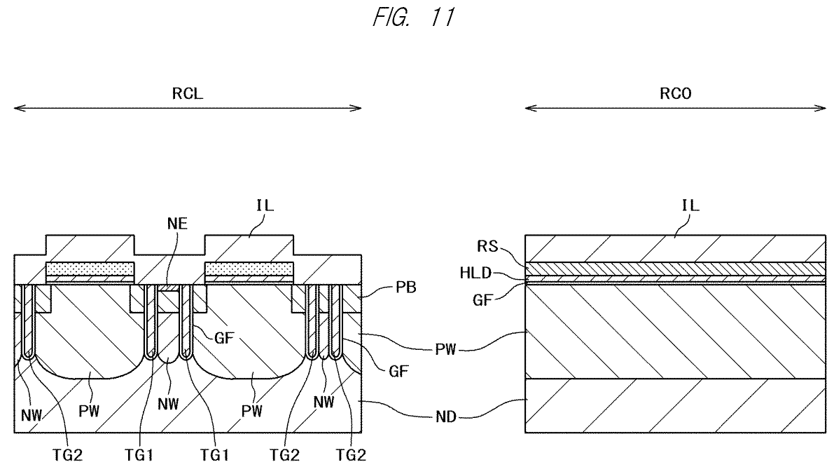

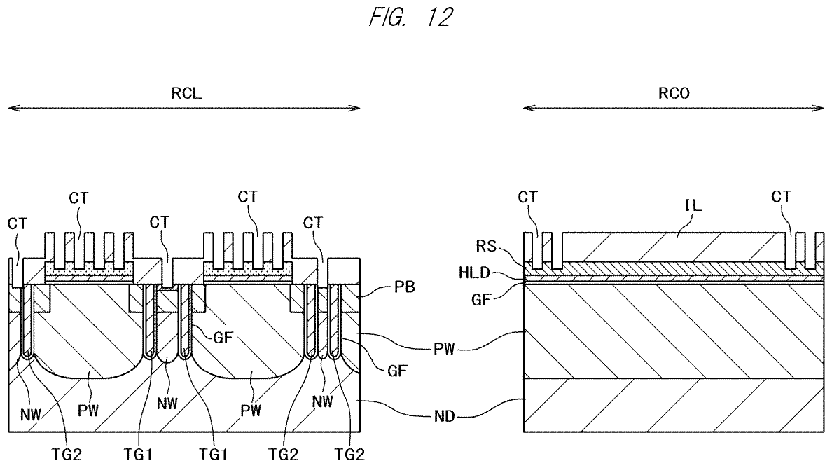

Next, as shown in FIG. 11, the interlayer insulating film IL is formed by, for example, the CVD method of depositing a silicon oxide film on the front surface of the wafer 1. More specifically, the interlayer insulating film IL is formed by depositing, for example, Phosphosilicate Glass (PSG) as a silicon oxide film. The interlayer insulating film IL is formed to cover the emitter region NE and the body region PB in the active cell region LCa, and the body region PB in the hole collector region LCc. The interlayer insulating film IL is formed to cover a stacked film composed of the body region PB, the gate insulating film GF, the second insulating film HLD, and the conductive film G2 in the inactive cell region LCi. The interlayer insulating film IL is formed to cover the resistance film RS in the cell peripheral connection region RCO. As a material for the interlayer insulating film IL, in addition to the PSG film, a Borophosphosilicate Glass (BPSG) film, a Non-doped Silicate Glass (NSG) film, a Spin-On-Glass (SOG) film, or a composite film thereof can be exemplified as suitable ones. Next, as shown in FIG. 12, the contact trench CT is formed in the interlayer insulating film IL by an anisotropic dry etching method using a resist pattern as a mask. Then, the body contact region PBC is formed by an ion implantation method of introducing a P-type impurity into the upper layer of the body region PB in the inactive session of the active cell region LCa and the hole collector cell region LCc through the contact trench CT. The body contact region PBC is also referred to as a P+ type body contact region.

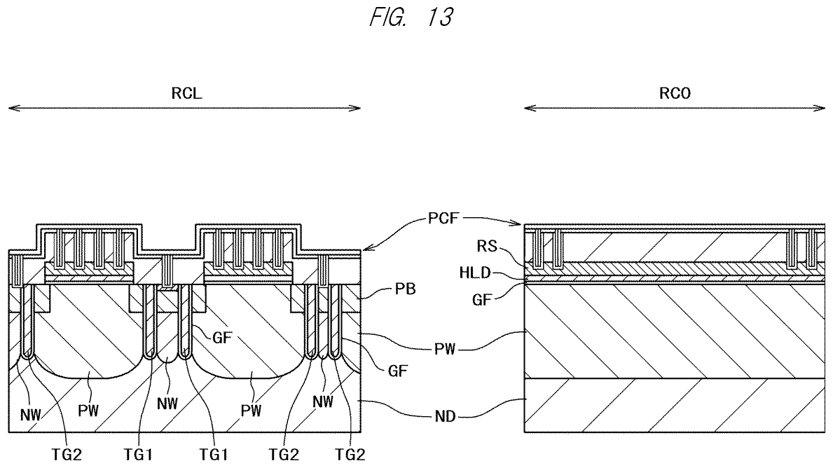

Next, as shown in FIG. 13, the conductive film PCF is formed by, for example, the sputtering method of depositing titanium (Ti) and titanium nitride (TiN) on the front surface of the wafer 1, and then, for example, the CVD method or the like of depositing tungsten (W) thereon.

Then, the conductive film PCF other than this in the contact trench CT is removed by, for example, the dry etching method of etching back the conductive film PCF. As a result, the first plug PL1 is formed in the active cell region LCa and the hole collector cell region LCc, and the second plug PL2 is formed in the inactive cell region LCi. Also, the third plug PL3 is formed in the cell peripheral connection region RC0. At this time, the first plug PL1, the second plug PL2, and the third plug PL3 are formed so that the center of the first plug PL1, the center of the second plug PL2, and the center of the third plug PL3 in plan view are receded (recessed).

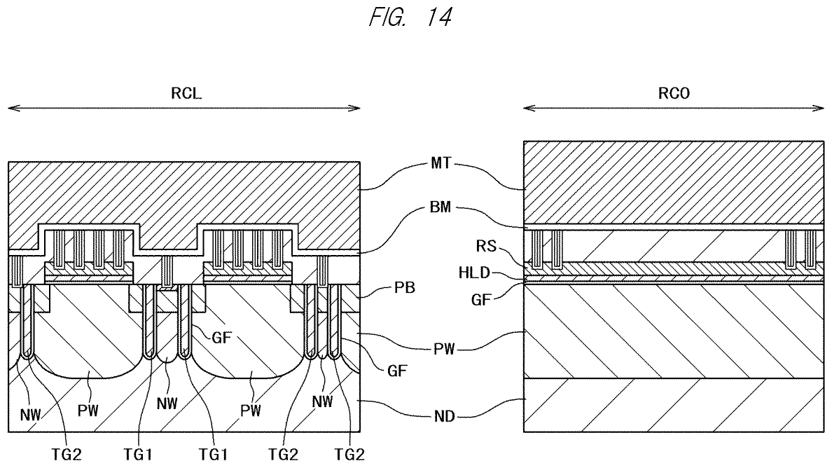

Next, the emitter electrode EE and the gate electrode GE are formed. Specifically, the formation is carried out by, for example, the following procedure. First, as shown in FIG. 14, the barrier metal film BM is formed by, for example, the sputtering method of depositing, for example, an alloy mainly composed of tungsten (W) or titanium tungsten (TiW) on the front surface of the wafer 1.

Then, the metal film MT is formed on the entire surface of the barrier metal film BM by, for example, the sputtering method of depositing an aluminum (Al) based metal on the front surface of the wafer 1.

Next, as shown in FIG. 15, the emitter electrode EE, the gate wiring GL, and the gate electrode GE including the metal film MT and the barrier metal film BM are formed by a dry etching method using a resist pattern as a mask. As a result, the emitter electrode EE, the gate wiring GL, and the gate electrode GE are formed on the interlayer insulating film IL.

Also, the emitter electrode EE is electrically connected to a plurality of emitter regions NE, a plurality of body contact regions PBC, and trench emitter electrodes TG2 formed in the active cell region LCa. The emitter electrode EE is electrically connected to the trench emitter electrode TG2 and the body contact region PBC formed in the hole collector cell region LCc. The gate wiring GL is electrically connected to the trench gate electrode TG1. Also, the gate wiring GL is electrically connected to one end of the resistance film RS. The gate electrode GE is electrically connected to the other end of the resistance film RS.

Note that the P-type well region PW in the cell forming region RCL becomes the floating region PF in FIG. 3, and the P-type well region PW in RP0 becomes the emitter potential region. The floating region PF is also referred to as a P-type floating region.

Next, an insulating film FPF is formed by depositing, for example, an organic material composed of polyimide as a main component on the front surface of the wafer 1. Then, an opening that penetrates the insulating film FPF and reaches the emitter electrode EE and the gate electrode GE is formed by a dry etching method of patterning the insulating film FPF, using a resist pattern as a mask.

Next, the emitter pad EP and the gate pad GP are formed by, for example, an electroless plating method of depositing, for example, nickel (Ni) and gold (Au) on the emitter electrode EE and the gate electrode GE in the exposed portions at the openings to form an OPM.

Next, the wafer 1 is thinned by performing a back grinding process on the back surface of the wafer 1. If necessary, chemical etching or the like is also performed for removing damage on the back surface of the wafer 1.

Next, an N-type field stop region Ns is formed by, for example, ion implantation of introducing an N-type impurity into the back surface of the wafer 1. The field stop region Ns is also referred to as an N-type field stop region. Then, if necessary, laser annealing or the like is performed on the back surface Sb of the wafer 1 for impurity activation.

Next, the P-type collector region PC is formed by, for example, ion implantation of introducing a P-type impurity into the back surface of the wafer 1. The collector region PC is also referred to as a P+ type collector region. Then, if necessary, laser annealing or the like is performed on the back surface of the wafer 1 for impurity activation.

Next, the metal film made of aluminum or the like is formed by, for example, sputtering to form the collector electrode CE electrically connected to the collector region PC, on the back surface of the wafer 1. As a result, as shown in FIG. 3, the collector region PC is provided in the semiconductor region on the back surface of the semiconductor chip, and the collector electrode CE is provided on its front surface. The field stop region Ns is provided between the collector region PC and the drift layer ND which constitutes the main portion of the substrate S. The emitter electrode EE, the gate electrode GE, and the collector electrode CE constitute the IGBT.

Then, the wafer 1 is divided into chip regions of the substrate S by dicing or the like, and then, the divided regions are sealed in a package if necessary, and the semiconductor device in the embodiment is substantially completed. The effects of the semiconductor device in the embodiment will be explained.

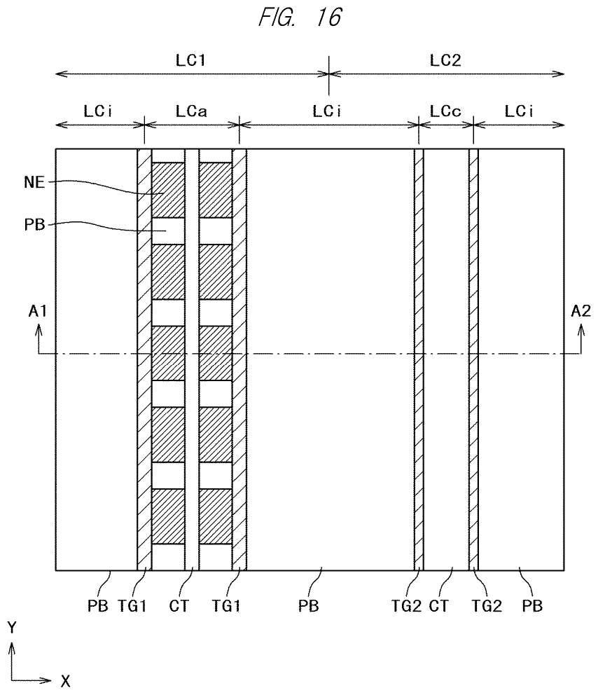

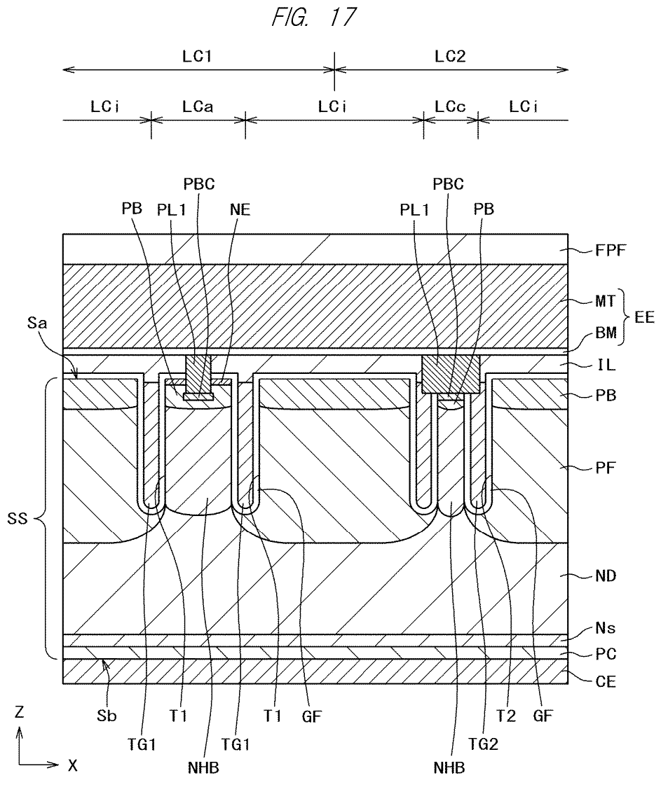

First, a technology (hereinafter referred to as a comparative example) studied prior to this disclosure by the present inventors will be explained using FIGS. 16 and 17. FIG. 16 is a plan view of the main portion of the semiconductor device in the comparative example. FIG. 17 is a cross-sectional view along line A1-A2 of the semiconductor device shown in FIG. 16.

The semiconductor device in the comparative example has a structure without the second insulating film HLD, the conductive film G2, and the second plug PL2 in the inactive cell region LCi compared to the semiconductor device in the embodiment shown in FIG. 3.

The emitter pad EP is electrically connected through solder to, for example, a clip which is a plate-like conductor made of copper (Cu) or the like. A peel-off test (hereinafter referred to as a copper plate peel-off test) is performed to evaluate the OPM. In the copper plate peel-off test of the semiconductor device of the comparative example, peeling may occur at not the interface between the OPM and the emitter electrode EE but the interface between the barrier metal film BM and the interlayer insulating film IL. In the copper plate peel-off test, the peeling occurring at the solder bulk causes a good product. Here, the emitter electrode EE is formed of a metal film mainly composed of aluminum (Al), the barrier metal film BM is formed of a titanium tungsten (TiW) film, and the first plug PL1 is formed of tungsten (W).

The reason why the peeling occurs at the interface between the barrier metal film BM and the interlayer insulating film IL in the semiconductor device of the comparative example will be explained.

### Structural Reason

Due to the structure of the plug contact, the barrier metal film BM (TiW film) makes contact with the upper surface of the plug and does not make contact with the inside of the contact trench CT. Therefore, the so-called anchor effect is considered to be small.

### Material Reason

A barrier metal film formed from a material containing tungsten (W) (here referred to as a W-based barrier metal film) and tungsten (W) have good adhesion due to the miscibility of the two metals. The W-based barrier metal film is an alloy film such as TiW mainly composed of W. On the other hand, the W-based barrier metal film and the silicon oxide film have a certain degree of adhesion. In particular, in the case of TiW, the adhesion to the silicon oxide film is relatively good due to the action of Ti. However, since the Ti content of TiW is about 10%, its adhesion is lower than that of the case with tungsten (W).

### Estimated Mechanism

When the shear stress during the peeling of the copper plate is applied to the interface between the barrier metal film BM and the interlayer insulating film IL, it is presumed that the interface is peeled off by the small anchor effect due to the above-mentioned structural reason. In particular, the IE type trench gate IGBT has a large area of a region where the floating region PF is formed, and therefore, there are few plugs. Therefore, it is presumed that it is more likely to peel off due to the above-mentioned material reason.

In the structure of the comparative example, there is nothing on the floating region PF, and the barrier metal film BM and the interlayer insulating film IL are adhered at a wide flat part. In contrast, in the embodiment, the adhesion between the barrier metal film BM and the interlayer insulating film IL is improved more than that of the comparative example by the anchor effect resulted from the formation of the plug structure on the flat part on the floating region PF to increase the contact area between the plug and the barrier metal film.

Also, as good materials for the miscibility between both metals of the barrier metal film BM and the plug, for example, the alloy film (for example, TiW) mainly composed of tungsten (W) is used as the barrier metal film BM, and tungsten (W) is used as the plug. By this, because of the contact between TiW and tungsten (W) in the plug, the adhesion between the barrier metal film BM and the interlayer insulating film IL is improved more than that of the Tiw-silicon oxide film which is the simple flat part interface as described in the comparative example.

### MODIFIED EXAMPLE

Hereinafter, some of typical modified examples of the embodiment will be exemplified. In the description of the following modified examples, the same reference numerals as those described in the above embodiment may be used for parts having the same configuration and function described in the above embodiment. And, to the description of such parts, the description in the above embodiment can be appropriately cited within the range where there is no technical contradiction. Also, part of the above embodiments and all or part of multiple modified examples can be appropriately and complexly applied within the range where there is no technical contradiction.

### First Modified Example

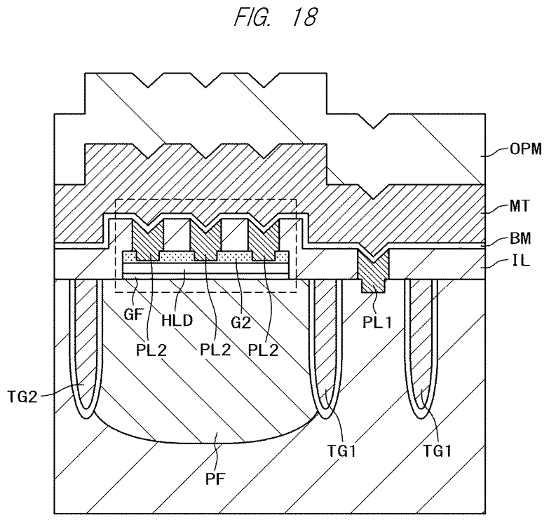

FIG. 18 is a schematic cross-sectional view showing a configuration of a semiconductor device in the first modified example. In FIG. 18, only the main portion of the substrate S is shown.

In the embodiment, by etching back the conductive film PCF, the first plug PL1 and the second plug PL2 are formed so that the central parts of the first plug PL1 and the second plug PL2 are receded (recessed) in plan view. In the first modified example, this recess is further enlarged, and as shown in FIG. 18, the upper surfaces of the first plug PL1 and the second plug PL2 are formed in a V shape. This can increase the contact areas between the barrier metal film BM and the first plug PL1 and the second plug PL2 more than that in the embodiment.

The V shapes of the upper surfaces of the plugs in the contact trench CT mentioned above can be obtained by adjusting the over-etching amount provided when the plug material is etched back.

In FIG. 3, note that the upper surfaces of the first plug PL1, the second plug PL2, the barrier metal film BM, the emitter electrode EE, and the insulating film FPF are depicted as being flat. However, as shown in FIG. 18, there are the second insulating film HLD, the conductive film G2, and the second plug PL2, and therefore, a step is formed.

Also, as shown in FIG. 18, the upper surfaces of the first plug PL1 and the second plug PL2 are formed in the V-shape, and therefore, the step is formed. Therefore, above the first plug PL1, the barrier metal film BM, the emitter electrode EE and the OPM functioning as the conductive film each has a cross-section that follows the V-shapes of the two plugs. Also, above the second plug PL2, the emitter electrode EE and the conductive film OPM are higher, and each has a cross-section that follows the V-shape of the second PL2.

### Second Modified Example

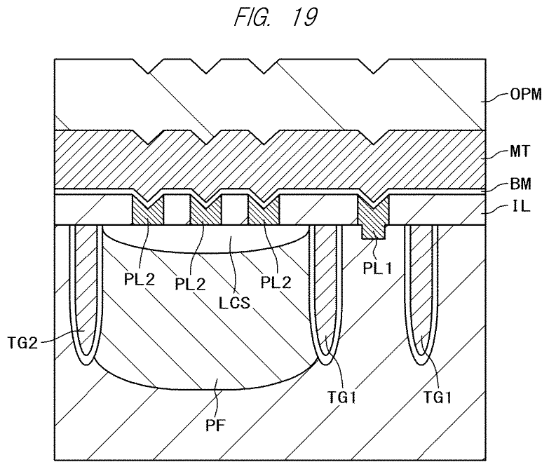

FIG. 19 is a schematic cross-sectional view showing a configuration of a semiconductor device in the second modified example. In FIG. 19, only the main portion of the substrate S is shown.

Instead of the gate insulating film GE, the second insulating film HLD, and the conductive film G2 in the embodiment, a separation insulating film LCS containing a silicon oxide film is formed on the upper part of the floating region PF by a LOCOS (Local Oxidation of Silicon) process. In a simple LOCOS process, when the contact trench is formed in the separation insulating film LCS on the floating region PF, there is a concern of penetration. In that case, it is preferable to use a recess LOCOS process. This can avoid the penetration.

The disclosure made by the present discloser has been specifically described based on the embodiments, but it goes without saying that the present disclosure is not limited to the above embodiments and can be variously modified. In the embodiment, the GGEE type IGBT was described, but it is not limited to this, and can be applied to the IE type trench gate IGBT with a wide floating region. That is, for example, it can also be applied to the GG type IGBT, EGE-S type IGBT, and GE-S type IGBT described in Japanese Unexamined Patent Application Publication No. 2019-29434.

Here, the GG type IGBT has the trench gate electrode between the active cell region and the inactive cell region, and the floating region is formed between the trench gate electrodes in the inactive cell region. The trench gate electrode penetrates the body region PB and the emitter region from the front surface side of the substrate and extends to the back surface side.

The EGE-S type IGBT has the trench emitter electrode between the active cell region and the inactive cell region, and has the trench gate electrode between the trench emitter electrodes in the active cell region. The floating region is formed between the trench emitter electrodes. The trench emitter electrode penetrates the body region PB and the emitter region from the front surface side of the substrate and extends to the back surface side.

The GE-S type IGBT has the trench gate electrode or the trench emitter electrode between the active cell region and the inactive cell region, and the trench gate electrode and the trench emitter electrode are provided to sandwich the inactive cell region. In other words, the floating region is formed between the trench gate electrode and the trench emitter electrode. The trench gate electrode penetrates the body region PB and the emitter region from the front surface side of the substrate and extends to the back surface side. The trench emitter electrode penetrates the body region PB and the emitter region from the front surface side of the substrate and extends to the back side.

What is claimed is:

1. A semiconductor device comprising:
a semiconductor substrate having a first main surface and a second main surface opposite to the first main surface;
a drift layer formed in the semiconductor substrate;
a body region formed on the drift layer;
an emitter region formed on the body region;
a trench gate electrode penetrating the body region and the emitter region from the first main surface and extending in a direction of the second main surface;
a trench emitter electrode formed adjacent to the trench gate electrode in plan view, penetrating the body region and extending in the direction of the second main surface;
a floating region formed between the trench gate electrode and the trench emitter electrode;
a stacked film formed on the floating region;
an interlayer insulating film formed on the stacked film and the body region;
a first plug penetrating the interlayer insulating film and reaching the body region;
a second plug penetrating the interlayer insulating film and reaching the stacked film;
a barrier metal film formed to cover the interlayer insulating film, the first plug, and the second plug; and
a metal film formed on the barrier metal film.

2. The semiconductor device according to claim 1,
wherein the barrier metal film is in contact with the interlayer insulating film, the first plug, and the second plug.

3. The semiconductor device according to claim 1,
wherein a plurality of the second plugs are formed on the floating region.

4. The semiconductor device according to claim 1,
wherein in plan view, the first plug and the second plug are formed such that a center of the first plug and a center of the second plug are recessed.

5. The semiconductor device according to claim 1,
wherein the first plug is electrically connected to the body region, and the second plug is not electrically connected to the floating region or the body region.

6. The semiconductor device according to claim 1,
wherein a material of the barrier metal film is an alloy film mainly composed of tungsten.

7. The semiconductor device according to claim 1,
wherein a material of the barrier metal film is titanium tungsten.

8. The semiconductor device according to claim 1,
wherein each material of the first plug and the second plug is tungsten.

9. The semiconductor device according to claim 1,
wherein the interlayer insulating film is a silicon oxide film.

10. The semiconductor device according to claim 1,
wherein in plan view, the stacked film has an end portion on the floating region, and a step is formed by the end portion.

11. The semiconductor device according to claim 10,
wherein the step is 50 nm or more in size.

12. The semiconductor device according to claim 1,
wherein the stacked film is a film in which a first insulating film, a second insulating film, and a conductive film are stacked in this order, and further includes a gate insulating film at each interface between the trench gate electrode and the semiconductor substrate and between the trench emitter electrode and the semiconductor substrate, and
wherein the first insulating film is formed in the same layer as the gate insulating film of the trench gate electrode and the trench emitter electrode.

13. The semiconductor device according to claim 1,
wherein the first plug is formed to span between the trench emitter electrode and the emitter region.

14. The semiconductor device according to claim 1,
wherein the trench gate electrode and the trench emitter electrode are adjacent in a first direction in plan view, and
wherein the trench gate electrode, the trench emitter electrode, the first plug, and the second plug extend in a second direction crossing the first direction in plan view.

15. The semiconductor device according to claim 1,
wherein the drift layer and the emitter region are of a first conductivity type, and
wherein the body region and the floating region are of a second conductivity type opposite to the first conductivity type.

16. The semiconductor device according to claim 1, further comprising:
a gate electrode formed on the first main surface and electrically connected to the trench gate electrode;
an emitter electrode formed on the first main surface and electrically connected to the trench emitter electrode; and
a collector electrode formed on the second main surface,
wherein the emitter electrode, the gate electrode, and the collector electrode constitute an IGBT.

17. A semiconductor device comprising:
a semiconductor substrate having a first main surface and a second main surface opposite to the first main surface;
a drift layer formed in the semiconductor substrate;
a body region formed on the drift layer;
an emitter region formed on the body region;
a trench gate electrode penetrating the body region and the emitter region from the first main surface and extending in a direction of the second main surface;
a trench emitter electrode formed adjacent to the trench gate electrode in plan view, penetrating the body region, and extending in the direction of the second main surface;
a floating region formed between the trench gate electrode and the trench emitter electrode;
a separation insulating film formed on the floating region;
an interlayer insulating film formed on the separation insulating film and the body region;
a first plug penetrating the interlayer insulating film and reaching the body region;
a second plug penetrating the interlayer insulating film and reaching the separation insulating film;
a barrier metal film formed to cover the interlayer insulating film, the first plug and the second plug; and
a metal film formed on the barrier metal film.

18. A method of manufacturing a semiconductor device, comprising steps of:
forming a drift layer in a semiconductor substrate having a first main surface and a second main surface opposite to the first main surface;
forming a body region on the drift layer;
forming an emitter region on the body region;
forming a trench gate electrode penetrating the body region and the emitter region and extending in a direction of the second main surface;
forming a trench emitter electrode adjacent to the trench gate electrode in plan view, penetrating the body region, and extending in the direction of the second main surface;
forming a floating region between the trench gate electrode and the trench emitter electrode;
forming a stacked film having a first insulating film, a second insulating film and a conductive film on the floating region;
forming an interlayer insulating film on the stacked film and the body region;
forming a first plug penetrating the interlayer insulating film and reaching the body region;
forming a second plug penetrating the interlayer insulating film and reaching the stacked film;
forming a barrier metal film to cover the interlayer insulating film, the first plug and the second plug; and
forming a metal film on the barrier metal film,
wherein the first insulating film is formed in the same layer as the gate insulating film of the trench gate electrode and the trench emitter electrode, and
wherein the first plug and the second plug are formed simultaneously.
